(19) United States
(12) Patent Application Publication
(10) Pub. No.: US 2026/0082542 A1
(43) Pub. Date: Mar. 19, 2026

(54) SEMICONDUCTOR DEVICE AND FABRICATION METHOD THEREOF

(71) Applicant: Yangtze Memory Technologies Co., Ltd., Wuhan (CN)

(72) Inventors: Hongshuai ZOU, Wuhan (CN); Zhen GUO, Wuhan (CN); Li JIANG, Wuhan (CN); Changhao SU, Wuhan (CN); He CHEN, Wuhan (CN); Wei XU, Wuhan (CN); Zongliang HUO, Wuhan (CN)

(21) Appl. No.: 18/978,845

(22) Filed: Dec. 12, 2024

Related U.S. Application Data
(63) Continuation of application No. PCT/CN2024/118947, filed on Sep. 14, 2024.

(51) Int. Cl. H10B 12/00

(52) U.S. Cl. CPC H10B 12/315; H10B 12/05

(57) ABSTRACT

Methods, devices, systems, and techniques for managing structure leakage in semiconductor devices are provided. In one aspect, a semiconductor device includes memory cells. Each memory cell includes a transistor having a semiconductor body and a gate structure. Gate structures of transistors of two adjacent memory cells extend along a first direction in a first trench structure. The semiconductor body includes first and second terminals at opposite ends of the semiconductor body along the first direction. The semiconductor device further includes a diffusion region including a first diffusion portion, a second diffusion portion, and a middle portion along the first direction. The diffusion region surrounds a first end of the first trench structure. A first area of the first trench structure surrounded by the first diffusion portion is greater than a second area of the first trench structure surrounded by the middle diffusion portion and the second diffusion portion.

### CROSS-REFERENCE TO RELATED APPLICATIONS

This application is a continuation of International Application No. PCT/CN2024/118947, filed on Sep. 14, 2024, the disclosure of which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The memory cells can include vertical structures, e.g., vertical transistors.

### SUMMARY

The present disclosure describes methods, devices, systems and techniques for managing vertical structures in three-dimensional (3D) semiconductor devices.

One aspect of the present disclosure features a semiconductor device. The semiconductor device includes memory cells, where a memory cell of the memory cells includes a transistor having a semiconductor body and a gate structure, where gate structures of transistors of two adjacent memory cells extend along a first direction in a first trench structure, and where the semiconductor body includes a first terminal and a second terminal at opposite ends of the semiconductor body along the first direction; and a diffusion region including a first diffusion portion, a second diffusion portion, and a middle portion between the first diffusion portion and the second diffusion portion along the first direction, the diffusion region surrounding a first end of the first trench structure, where the first end of the first trench structure is closer to the second terminal than the first terminal along the first direction, where a first area of the first trench structure surrounded by the first diffusion portion is greater than a second area of the first trench structure surrounded by the middle diffusion portion and the second diffusion portion.

In some implementations, the first diffusion portion has a first curved boundary, and the second diffusion portion has a second curved boundary, and where the first curved boundary and the second curved boundary are in contact at ends of the middle portion.

In some implementations, the first curved boundary is in contact with the first trench structure at a contact position, and wherein, along the first direction, a first length between the contact position and the ends of the middle portion is greater than a second length between the ends of the middle portion and the first end of the first trench structure.

In some implementations, the first trench structure further includes an isolation structure in at least a portion of the first trench structure from a second end of the first trench structure, the second end of the first trench structure being closer to the first terminal than the second terminal along the first direction, where the gate structures are surrounded by the isolation structure along the second direction; and an isolation space defined by a remaining portion of the first trench structure from the first end of the first trench structure along the first direction, where the isolation space extends into a portion of the isolation structure along the first direction, and where the isolation space is in contact with the gate structures.

In some implementations, along the first direction, a length of the first trench structure surrounded by the diffusion region is greater than a length from an end of the isolation structure to the first end of the first trench structure, the end of the isolation structure being closer to the second terminal than the first terminal along the first direction.

In some implementations, along the first direction, a length from the end of the isolation structure to the first terminal is greater than a length from an edge of the first diffusion portion to the first terminal along the first direction.

In some implementations, along the first direction, the end of the isolation structure is farther from the first terminal of the transistor than an end of the gate structure, the end of the gate structure being closer to the second terminal than the first terminal along the first direction.

In some implementations, along the first direction, a length from the first end of the first trench structure to an edge of the second diffusion portion is in a range from 20 nm to 40 nm, the edge of the second diffusion portion being closer to the second terminal than the first terminal.

In some implementations, the semiconductor device further includes at least one bit line layer stacked with the memory cells along the first direction, where the at least one bit line layer is coupled to the second terminal of the two adjacent memory cells through an ohmic contact.

In some implementations, the first diffusion portion has a first concentration profile of a dopant, and the second diffusion portion has a second concentration profile of the dopant, and where the middle portion has a third concentration profile of the dopant, and the third concentration profile is based on the first concentration profile and the second concentration profile.

In some implementations, a concentration of the diffusion region has at least three peaks along the first direction, where a first peak is located in the first diffusion portion, a second peak is located in the middle portion, and a third peak is located in the second diffusion portion.

In some implementations, the semiconductor device further includes a second trench structure extending along the first direction and between two adjacent first trench structures along a second direction perpendicular to the first direction, where two adjacent diffusion regions associated with the two adjacent first trench structures are spaced from the second trench structure.

Another aspect of the present disclosure features a method of forming a semiconductor device. The method includes forming memory cells on a semiconductor substrate, where a memory cell of the memory cells includes a transistor having a semiconductor body and a gate structure, where gate structures of transistors of two adjacent memory cells extend along a first direction in a first trench structure, and where the semiconductor body includes a first terminal and a second terminal at opposite ends of the semiconductor body along the first direction; and forming a diffusion region including a first diffusion portion, a second diffusion portion, and a middle portion between the first diffusion portion and the second diffusion portion along the first direction, the diffusion region surrounding a first end of the first trench structure, where the first end of the first trench structure is closer to the second terminal than the first terminal along the first direction, where a first area of the first trench structure surrounded by the first diffusion portion is greater than a second area of the first trench structure surrounded by the middle diffusion portion and the second diffusion portion.

In some implementations, the method further includes forming the first trench structure, where forming the first trench structure includes etching a portion of the semiconductor substrate along the first direction to form a first trench, where forming the diffusion region includes implanting a dopant at an end of the first trench with a first concentration profile of the dopant to form a first diffusion region; deepening the first trench by etching the first diffusion region from the end of the first trench along the first direction into the first diffusion region in the semiconductor substrate to form a second trench; and implanting the dopant at a first end of the second trench with a second concentration profile of the dopant to form a second diffusion region, where an overlap region of the first diffusion region and the second diffusion region forms the middle diffusion portion, and the first diffusion portion is defined by the first diffusion region without the overlap region, and the second diffusion portion is defined by the second diffusion region without the overlap region, and where the first diffusion portion has a first curved boundary, and the second diffusion portion has a second curved boundary, and where the first curved boundary and the second curved boundary are in contact at ends of the middle portion.

In some implementations, the middle portion has a third concentration profile of the dopant, and the third concentration profile is based on the first concentration profile and the second concentration profile, and where a concentration of the diffusion region has at least three peaks along the first direction, where a first peak is located in the first diffusion portion, a second peak is located in the middle portion, and a third peak is located in the second diffusion portion.

In some implementations, forming the first trench structure further includes depositing one or more filling layers in the second trench, where the one or more filling layers include an isolation layer, an adhesive layer, and a conductive layer; filling a remaining portion of the second trench with an isolation material to form an isolation stack; removing a portion of the adhesive layer and the conductive layer from a second end of the second trench to form a space; and filling the space with the isolating material connected to the isolation layer and the isolation stack to form an isolation structure.

In some implementations, forming the first trench structure further includes forming an isolation space, where forming the isolation space includes etching a portion of the isolation layer in the second trench from the first end of the second trench; and etching a portion of the adhesive layer and the conductive layer from the first end of the second trench to form the isolation space, where gate structures of transistors of two adjacent memory cells include remaining portions of the adhesive layer and the conductive layer.

In some implementations, the method further includes forming at least one bit line layer stacked with the memory cells along the first direction, where the at least one bit line layer is coupled to the second terminal of the two adjacent memory cells through an ohmic contact.

In some implementations, the method further includes forming a second trench structure extending along the first direction and between two adjacent first trench structures along a second direction perpendicular to the first direction, where two adjacent diffusion regions associated with the two adjacent first trench structures are spaced from the second trench structure.

A further aspect of the present disclosure features a semiconductor device. The semiconductor device includes memory cells, where a memory cell of the memory cells includes a transistor having a semiconductor body and a gate structure, where gate structures of transistors of two adjacent memory cells extend along a first direction in a first trench structure, and where the semiconductor body includes a first terminal and a second terminal at opposite ends of the semiconductor body along the first direction; and a diffusion region that surrounds a first end of the first trench structure, where the first end of the first trench structure is closer to the second terminal than the first terminal along the first direction, where the diffusion region includes a first curved region and a second curved region, and wherein, along the first direction, a first length of the first trench structure surrounded by the first curved region is greater than a second length of the first trench structure surrounded by the second curved region.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A-1B illustrate a cross-section view of an example semiconductor device.

FIG. 1C illustrates a cross-section view of an example semiconductor device.

FIG. 1D illustrates a top view of an example semiconductor device.

FIG. 2A-2O illustrate an example process of manufacturing a semiconductor device.

FIG. 3 illustrates a flow chart of an example process of manufacturing a semiconductor device.

FIG. 4 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for cheaper memory devices with a higher density, a memory device (e.g., a DRAM memory) can be formed to have a vertical transistor with a single diffusion region in the active area. The vertical transistor can include a gate structure that extends along a first direction in a trench structure. A first end of the single diffusion region is in contact with at least one bit line layer, and a second end of the single diffusion region surrounds the bottom of the trench structure. The structure of the vertical transistor of such memory devices may pose challenges to the manufacturing process. For example, the single diffusion region of the memory cell may not be sufficient to cover traps formed on the active area surface during the fabrication process. In other words, the traps may pose challenges in controlling the leakage current of the channel structure. In another example, the concentration of a dopant in a single diffusion region may not be sufficient to form an ohmic contact between the memory cell and the at least one bit line layer. Therefore, a vertical transistor that can solve the aforementioned issues is desirable.

In one or more implementations of the present disclosure, an example semiconductor device is provided. The semiconductor device includes memory cells, and a memory cell of the memory cells includes a transistor having a semiconductor body and a gate structure. Gate structures of transistors of two adjacent memory cells extend along a first direction in a first trench structure. The semiconductor body includes a first terminal and a second terminal at opposite ends of the semiconductor body along the first direction. The semiconductor device further includes a diffusion region having a first diffusion portion, a second diffusion portion, and a middle portion between the first diffusion portion and the second diffusion portion along the first direction. The diffusion region surrounds a first end of the first trench structure, and the first end of the first trench structure is closer to the second terminal than the first terminal along the first direction. A first area of the first trench structure surrounded by the first diffusion portion is greater than a second area of the first trench structure surrounded by the middle diffusion portion and the second diffusion portion.

Implementations of the present disclosure can provide one or more of the following technical advantages and/or benefits. For example, in the example semiconductor device described above, the first trench structure can be formed with a two-step etching process to ensure a low critical dimension of the trench structure. Moreover, the diffusion profiles of the two diffusion portions of the diffusion region in the example semiconductor device can be precisely controlled. Thus, the target dopant concentration of the two diffusion portions of the diffusion region can be achieved to cover the trap produced during the fabrication process, thereby achieving a lower leakage current and a longer retention time in the memory cells. Additionally, the second diffusion portion of the diffusion region can be connected to at least one bit line layer, thereby effectively improving the ohmic contact between the vertical transistor of the memory cell and the bit line layer. In other words, the techniques disclosed herein can effectively reduce the resistance at the interface between the vertical transistor of the memory cell and at least one bit line layer, thereby improving the trap-mediated leakage current.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

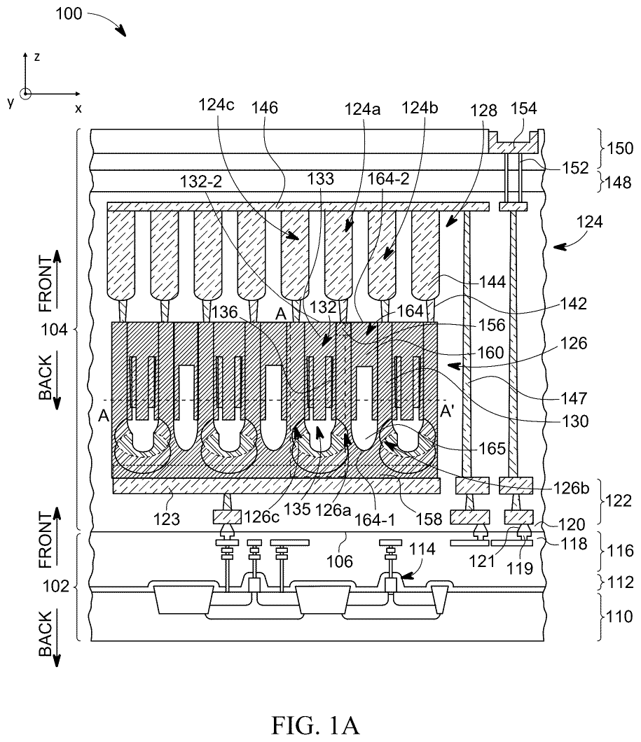

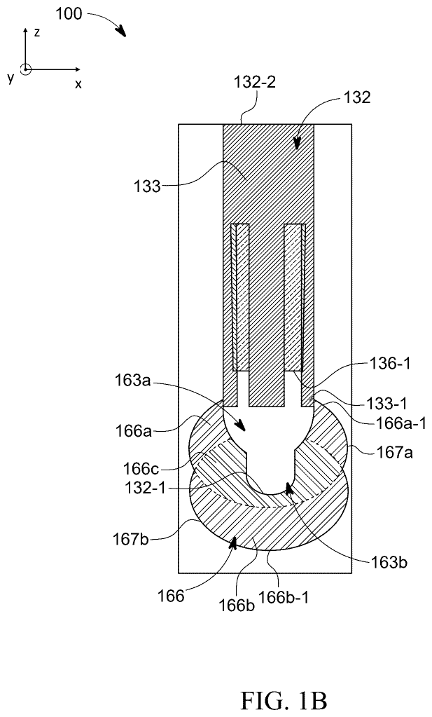

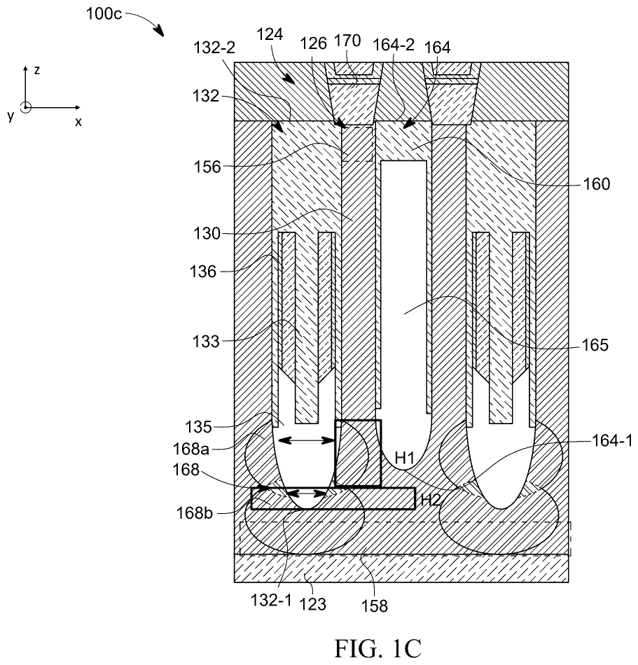

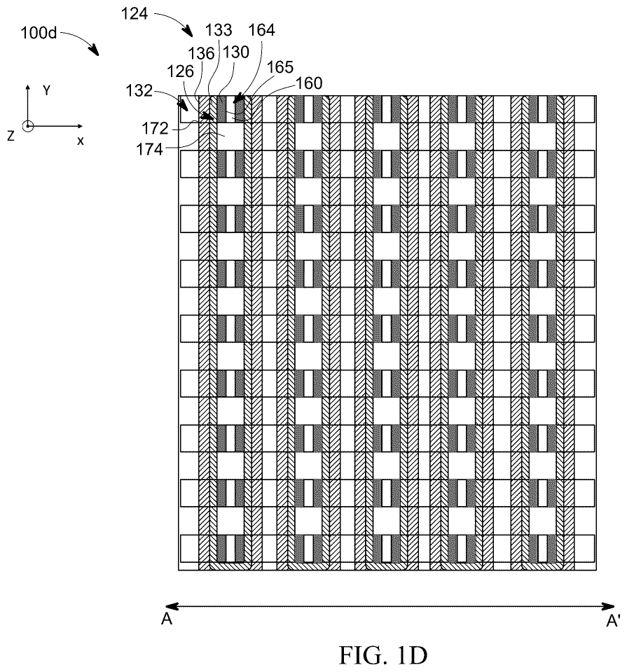

It is noted that X, Y, and Z axes (also referred to as X, Y, and Z directions) are included in FIGS. 1A-1C to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1A illustrates a side view of a cross-section of an example 3D semiconductor device 100. The 3D semiconductor device 100 can be a 3D dynamic random-access memory (DRAM). It is understood that FIG. 1A is for illustrative purposes only and may not necessarily reflect the actual device structure (e.g., interconnections) in practice. In some implementations, the 3D semiconductor device 100 is a bonded chip including a first semiconductor structure 102 and a second semiconductor structure 104 stacked over the first semiconductor structure 102. The first and second semiconductor structures 102 and 104 can be jointed at bonding interface 106 therebetween.

As shown in FIG. 1A, the first semiconductor structure 102 can include a substrate 110, which can include silicon (e.g., single crystalline silicon, c-Si), SiGe, GaAs, Ge, SOI, or any other suitable materials. The first semiconductor structure 102 can include peripheral circuits 112 on and/or in the substrate 110. In some implementations, the peripheral circuits 112 include a plurality of transistors 114 (e.g., planar transistors and/or 3D transistors). Trench isolations (e.g., shallow trench isolations (STIs)) and doped regions (e.g., wells, sources, and drains of transistors 114) can be formed on or in the substrate 110 as well. In some examples, the peripheral circuits 112 are formed using complementary metal-oxide-semiconductor (CMOS) technology, and the first semiconductor structure 102 can be also formed on a semiconductor die that can be referred to as a control die or a CMOS die 102.

In some implementations, the first semiconductor structure 102 further includes an interconnect layer 116 above the peripheral circuits 112 to transfer electrical signals to and from the peripheral circuits 112. The interconnect layer 116 can include a plurality of interconnects (also referred to herein as “contacts”), including lateral interconnect lines and VIA contacts. The interconnect layer 116 can further include one or more interlay dielectric (ILD) layers in which the interconnect lines and via contacts can form. That is, the interconnect layer 116 can include interconnect lines and via contacts in multiple ILD layers. In some implementations, peripheral circuits 112 are coupled to one another through the interconnects in the interconnect layer 116. The interconnects in interconnect layer 116 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 1A, the first semiconductor structure 102 has a front side and a back side, and the first semiconductor structure 102 can further include a bonding layer 118 at the back side at the bonding interface 106 and above the interconnect layer 116 and the peripheral circuits 112. The bonding layer 118 can include a plurality of bonding contacts 119 and dielectrics electrically isolating the bonding contacts 119. The bonding contacts 119 can include conductive materials, such as Cu. The remaining area of the bonding layer 118 can be formed with dielectric materials, such as silicon oxide. The bonding contacts 119 and surrounding dielectrics in the bonding layer 118 can be used for hybrid bonding. Similarly, as shown in FIG. 1A, the second semiconductor structure 104 can also include a bonding layer 120 at the bonding interface 106 and above the bonding layer 118 of the first semiconductor structure 102. The bonding layer 120 can include a plurality of bonding contacts 121 and dielectrics electrically isolating the bonding contacts 121. The bonding contacts 121 can include conductive materials, such as Cu. The remaining area of the bonding layer 120 can be formed with dielectric materials, such as silicon oxide. The bonding contacts 121 and surrounding dielectrics in the bonding layer 120 can be used for hybrid bonding. The bonding contacts 121 can be in contact with the bonding contacts 119 at the bonding interface 106. In some implementations, the bonding layer 120 includes a dielectric layer opposing memory cells (e.g., DRAM cells) 124 with at least one bit line layer 123 positioned between the dielectric layer and the memory cells 124, as shown in FIG. 1A. The dielectric layer can include the bonding interface 106 having the bonding contacts 121.

The second semiconductor structure 104 can be bonded on top of the first semiconductor structure 102 in a face-to-face manner at the bonding interface 106. In some implementations, the bonding interface 106 is disposed between the bonding layers 120 and 118 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 106 is the place at which bonding layers 120 and 118 are met and bonded. In some examples, the bonding interface 106 can be a layer with a certain thickness that includes the top surface of the bonding layer 118 of the first semiconductor structure 102 and the bottom surface of the bonding layer 120 of the second semiconductor structure 104.

In some implementations, the second semiconductor structure 104 further includes an interconnect layer 122 including the at least one bit line layer 123 above the bonding layer 120 to transfer electrical signals. The interconnect layer 122 can include a plurality of interconnects, such as mid end of line (MEOL) interconnects and back end of line (BEOL) interconnects. In some implementations, the interconnects in interconnect layer 122 also include local interconnects, such as the at least one bit line layer 123 and word line contacts (not shown). The interconnect layer 122 can further include one or more ILD layers in which the interconnect lines and via contacts can form. The interconnects in the interconnect layer 122 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the peripheral circuits 112 include a word line driver/row decoder coupled to the word line contacts in the interconnect layer 122 through the bonding contacts 121 and 119 in the bonding layers 120 and 118 and the interconnect layer 116. In some implementations, the peripheral circuits 112 include a bit line driver/column decoder coupled to the at least one bit line layer 123 and bit line contacts in the interconnect layer 122 through the bonding contacts 121 and 119 in the bonding layers 120 and 118 and the interconnect layer 116. In some implementations, the at least one bit line layer 123 is a metal bit line, as opposed to semiconductor bit lines (e.g., doped silicon bit lines). For example, the at least one bit line layer 123 may include W, Co, Cu, Al, or any other suitable metals having higher conductivities than doped silicon. In some implementations, the at least one bit line layer contact is an ohmic contact as opposed to a Schottky contact.

In some implementations, the at least one bit line layer 123 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon. In some implementations, the at least one bit line layer 123 can include more than one conductive layer and more than one dielectric layer alternating with each other along the Z direction.

In some implementations, the second semiconductor structure 104 includes a DRAM device in which memory cells are provided in the form of an array of DRAM cells 124 above the interconnect layer 122 and the bonding layer 120. That is, the interconnect layer 122 including the at least one bit line layer 123 can be disposed between bonding layer 120 and array of DRAM cells 124. At least one bit line 123 in the interconnect layer 122 can be coupled to a string of DRAM cells 124. In some implementations, the second semiconductor structure 104 is formed on a semiconductor die and can be referred to as array die 104.

In some implementations, a semiconductor device can include multiple array dies (e.g., the array die 104) and a CMOS die (e.g., the CMOS die 102). The multiple array dies and the CMOS die can be stacked and bonded together. The CMOS die can be respectively coupled to each of the multiple array dies and can respectively drive each of the multiple array dies to operate in the similar manner as the semiconductor device. The semiconductor device can be any suitable device. In some examples, the semiconductor device includes at least a first wafer and a second wafer bonded face to face. The array die can be disposed with other array dies on the first wafer, and the CMOS die can be disposed with other CMOS dies on the second wafer. The first wafer and the second wafer can be bonded together, thus the array dies on the first wafer can be bonded with corresponding CMOS dies on the second wafer. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate.

Each memory cell 124 can include a vertical transistor 126 and a capacitor 128 coupled to the vertical transistor 126. The memory cell 124 can be a 1T1C cell consisting of one transistor (T) and one capacitor (C). It is understood that the memory cell 124 may be of any suitable configurations, such as 2T1C cell, 3T1C cell, etc. The vertical transistor 126 can be a MOSFET used to switch a respective memory cell 124. In some implementations, the vertical transistor 126 includes a semiconductor body 130 extending vertically (in the Z direction), and a gate structure 136 that extends along the Z direction in a first trench structure 132. The first trench structure 132 is in contact with one side of the semiconductor body 130. The semiconductor body 130 can have a cuboid shape or a cylinder shape. In some implementations, the vertical transistor 126 has a structure including two or more gates, e.g., a two-gates structure, a three-gates structure, or a gate all around (GAA) structure. In some implementations, the gate structure 136 includes a gate electrode and a gate dielectric laterally between the gate electrode and the semiconductor body 130 in a second horizontal direction (e.g., in the Y direction) perpendicular to the Z direction and the X direction. In some implementations, the semiconductor body 130 can have a first terminal 156 in the positive z-direction and a second terminal 158 opposite the first terminal 156 in the negative z-direction, as shown in FIG. 1A. In some implementations, the first trench structure 132 can include a first isolation structure 133 in at least a portion of the first trench structure 132 from a second end 132-2 of the first trench structure 132, the second end 132-2 of the first trench structure 132 being closer to the first terminal 156 than the second terminal 158 along the Z direction. The gate structures 136 are surrounded by the first isolation structure 133 along the X direction. In some implementations, the first trench structure 132 can include a first isolation space 135 defined by a remaining portion of the first trench structure 132 from a first end 132-1 of the first trench structure 132 along the Z direction. The first isolation space 135 extends into a portion of the first isolation structure 133 along the Z direction. In some implementations, the first isolation space 135 is in contact the with gate structures 136. In some implementations, a length of the first trench structure 132 along the Z direction is in a range from about 255 nm to about 275 nm. In some implementations, a length of the gate structure 136 along the Z direction is in a range from about 80 nm to about 90 nm.

Each vertical transistor 126 of the memory cell 124 can include a second trench structure 164. The second trench structure 164 is between a first vertical transistor 126a of a first memory cell 124a and a second vertical transistor 126b of a second memory cell 124b. In some implementations, the first terminal 156 of the vertical transistor 126 and the second terminal 158 of the vertical transistor 126 are at the opposite ends of the semiconductor body 130 of the memory cell 124 along the Z direction, and the second trench structure 164 is between two adjacent first trench structures 132 along the X direction. In some implementations, the second trench structure can include a second isolation structure 160 in at least a portion of the second trench structure 164 from a second end 164-2 of the second trench structure 164. The second end 164-2 of the second trench structure 164 is closer to the first terminal 156 of the vertical transistor 126a of the memory cell 124a than the second terminal 158 of the vertical transistor 126a of the memory cell 124a along the Z direction. In some implementations, the second trench structure 164 can include a second isolation space 165 defined by a remaining portion of the second trench structure 164 from the first end 164-1 of the second trench structure 164 along the Z direction. The second isolation space 165 extends into a portion of the second isolation structure 160 along the Z direction.

FIG. 1B illustrates a side view of a cross-section of an example 3D semiconductor device 100 zoomed in on zone A in FIG. 1A. As shown in FIGS. 1A-1B, in some implementations, the semiconductor device 100 can include a diffusion region 166. The diffusion region includes a first diffusion portion 166a, a second diffusion portion 166b, and a middle diffusion portion 166c between the first diffusion portion 166a and the second diffusion portion 166b along the Z direction. The diffusion region 166 surrounds the first end 132-1 of the first trench structure 132 of the first vertical transistor 126a of the first memory cell 124a. A first area 163a of the first trench structure 132 surrounded by the first diffusion portion 166a is greater than a second area 163b of the first trench structure surrounded by the middle diffusion portion 166c and the second diffusion portion 166b. In some implementations, the first diffusion portion 166a has a first curved boundary 167a and the second diffusion portion 166b has a second curved boundary 167b. The first curved boundary 167a and the second curved boundary 167b are in contact at ends of the middle diffusion portion 166c. In some implementations, the first curved boundary 167a is in contact with the first trench structure 132 of the vertical transistor 126a of the first memory cell 124a at a contact position, and a first length between the contact position and the ends of the middle diffusion portion 166c is greater than a second length between the ends of the middle portion and the first end 132-1 of the first trench structure 132 along the Z direction. In some implementations, a length of the first trench structure 132 of the vertical transistor 126a of the first memory cell 124a surrounded by the diffusion region 166 is greater than a length from an end 133-1 of the first isolation structure 133 to the first end 132-1 of the first trench structure 132 along the Z direction. The end 133-1 of the first isolation structure 133 is closer to the second terminal 158 of the vertical transistor 126a of the memory cell 124a than the first terminal 156 of the vertical transistor 126a of the memory cell 124a along the Z direction. In some implementations, a length from the end 133-1 of the first isolation structure 133 to the first terminal 156 of the vertical transistor 126a of the first memory cell 124a is greater than a length from an edge 166a-1 of the first diffusion portion 166a to the first terminal 156 of the vertical transistor 126a of the first memory cell 124a along the Z direction. In some implementations, the end 133-1 of the first isolation structure 133 is farther from the first terminal 156 of the vertical transistor 126a of the memory cell 124a than an end 136-1 of the gate structure 136 of the vertical transistor 126a of the memory cell 124a. The end 136-1 of the gate structure 136 of the vertical transistor 126a of the memory cell 124a is closer to the second terminal 158 of the vertical transistor 126a of the memory cell 124a than the first terminal 156 of the vertical transistor 126a of the memory cell 124a along the Z direction. In some implementations, a length from the first end 132-1 of the first trench structure 132 of the vertical transistor 126a of the memory cell 124a to an edge 166b-1 of the second diffusion portion 166b is in a range from 20 nm to 40 nm. The edge 166b-1 of the second diffusion portion 166b is closer to the second terminal 158 of the vertical transistor 126a of the memory cell 124a than the first terminal 156 of the vertical transistor 126a of the memory cell 124a. In some implementations, the first diffusion portion 166a has a first concentration profile of a dopant, and the second diffusion portion 166b has a second concentration profile of the dopant. The middle diffusion portion 166c has a third concentration profile of the dopant, and the third concentration profile is based on the first concentration profile and the second concentration profile. In some implementations, a concentration of the diffusion region 166 has at least three peaks along the Z direction. In some implementations, a first peak is located in the first diffusion portion 166a, a second peak is located in the middle diffusion portion 166c, and a third peak is located in the second diffusion portion 166b. In some implementations, a number of concentration peak is greater than 3 and each diffusion portion 166a, 166b, and 166c can have more than 1 concentration peaks.

As shown in FIG. 1A, the semiconductor device 100 can include a third memory cell 124c. In some implementations, the first memory cell 124a is between the second memory cell 124b and the third memory cell 124c along the X direction. In some implementations, as shown in FIG. 1A, the first trench structure 132 can include two gate structures 136 of two vertical transistors 126a and 126c of the first memory cell 124a and the third memory cell 124c. In some implementations, as shown in FIG. 1A, the first terminal 156 the vertical transistor 126a of the first memory cell 124a is coupled to the capacitor 128 and the second terminal 158 is couple to the at least one bit line layer 123. In some implementation, the at least one bit line layer 123 is coupled to the second terminal 158 of the two adjacent memory cells 124 through an ohmic contact. In some implementations, the first terminal 156 can be a source structure and the second terminal 158 can be a drain structure. In some implementations, the second terminal 158 of the memory cells 124 form a single second terminal 158. The second terminal 158 is connected to the corresponding at least one bit line layer 123 through an ohmic contact.

In some implementations, the semiconductor body 130 includes a semiconductor material, such as single crystalline silicon, polysilicon, amorphous silicon, Ge, any other semiconductor material, or any combinations thereof. In one example, semiconductor body 130 may include single crystalline silicon. The first terminal 156 and the second terminal 158 can be doped with N+ type dopants (e.g., Phosphorus (P) or Arsenic (As)) or P-type dopants (e.g., Boron (B) or Gallium (Ga)) at a desired doping level. In some implementations, a silicide layer, such as a metal silicide layer, is formed between the second terminal 158 of the vertical transistor 126 and the at least one bit line layer 123 as the bit line contact or the first terminal 156 of the vertical transistor 126 and the first electrode of the capacitor 128 as capacitor contact 142 to reduce the contact resistance. In some implementations, gate dielectric includes dielectric materials, such as silicon oxide, silicon nitride, or high-k dielectrics including, but not limited to, Al2O3, HfO2, Ta2O5, ZrO2, TiO2, or any combination thereof. In some implementations, gate electrode includes a conductive material including, but not limited to W, Co, Cu, Al, TiN, TaN, polysilicon, silicide, or any combination thereof. In some implementations, the gate electrode includes multiple conductive layers, such as a W layer over a TiN layer. In one example, the gate structure 136 may be a “gate oxide/gate poly” gate in which the gate dielectric includes silicon oxide and gate electrode includes doped polysilicon. In another example, gate structure 136 may be an HKMG in which the gate dielectric includes a high-k dielectric and the gate electrode includes a metal.

As described above, since the gate structure 136 may be part of a word line or extend in the word line direction (e.g., the X direction) as a word line, the second semiconductor structure 104 of the 3D semiconductor device 100 can also include a plurality of word lines each extending in the word line direction. Each word line can be coupled to a row of DRAM cells 124. That is, the at least one bit line layer 123 and the word line can extend in two perpendicular lateral directions, and the semiconductor body 130 of the vertical transistor 126 can extend in the vertical direction perpendicular to the two lateral directions in which the at least one bit line layer 123 and the word line extend. Word lines are in contact with word line contacts (not shown). In some implementations, the word lines include conductive materials including, but not limited to W, Co, Cu, Al, TiN, TaN, polysilicon, silicides, or any combination thereof. In some implementations, the word line includes multiple conductive layers, such as a W layer over a TiN layer, as shown in FIG. 1A.

In some implementations, as shown in FIG. 1A, the vertical transistors 126 can be arranged in a mirror-symmetric manner to increase the density of the memory cells 124 in a second horizontal direction perpendicular to the Z direction and the X direction (the Y direction). As shown in FIG. 1A, two adjacent vertical transistors 126 in the Y direction are mirror-symmetric to one another with respect to the second trench structure 164. That is, the second semiconductor structure 104 can include a plurality of the second trench structures 164 each extending in the X direction in parallel with word lines and disposed between vertical gates of two adjacent rows of the vertical transistors 126. Each of the first trench structures can include two gate structures 136 of two memory cells. In some implementations, the rows of vertical transistors 126 separated by the second trench structure 164 are mirror-symmetric to one another with respect to the second trench structure 164.

As shown in FIG. 1A, in some implementations, a capacitor 128 includes a first electrode 144 above and coupled to the first terminal 156 of the vertical transistor 126 via a capacitor contact 142. In some implementations, the capacitor contact 142 is an ohmic contact, such as a metal silicide contact, as opposed to a Schottky contact. For example, the capacitor contact 142 may include metal silicides, such as WSi, CoSi, CuSi, AlSi, or any other suitable metal silicides having higher conductivities than doped silicon. The capacitor 128 can also include a capacitor dielectric above and in contact with the first electrode 144, and a second electrode above and in contact with the capacitor dielectric. That is, the capacitor 128 can be a vertical capacitor in which the electrodes and capacitor dielectric are stacked vertically (in the z-direction), and the capacitor dielectric can be sandwiched between the electrodes. In some implementations, each first electrode is coupled to the first terminal 156 of a respective vertical transistor 126 in the same memory cell 124, while all second electrodes are coupled to a common plate 146 coupled to the ground, e.g., a common ground. The capacitor 128 can have a first end in the negative z-direction and a second end opposite the first end in the positive z-direction, as shown in FIG. 1A. As shown in FIG. 1A, the second semiconductor structure 104 can further include a capacitor contact 147 (e.g., a conductor) in contact with a common plate 146 for coupling the capacitors 128 to the peripheral circuits 112 or to the ground directly. In some implementations, the capacitor contact 147 (e.g., a conductor) extends in the z-direction from the dielectric layer of the bonding layer 120 to couple to the second end of the capacitor 128 via the common plate 146, as shown in FIG. 1A. In some implementations, the ILD layer in which the capacitors 128 are formed has the same dielectric material as the two ILD layers into which the semiconductor body 130 extends, such as silicon oxide.

It is understood that the structure and configuration of a capacitor 128 are not limited to the example in FIG. 1A and may include any suitable structure and configuration, such as a planar capacitor, a stack capacitor, a multi-fins capacitor, a cylinder capacitor, a trench capacitor, or a substrate-plate capacitor. In some implementations, the capacitor dielectric includes dielectric materials, such as silicon oxide, silicon nitride, or high-k dielectrics including, but not limited to, Al2O3, HfO2, Ta2O5, ZrO2, TiO2, or any combination thereof. It is understood that in some examples, a capacitor 128 may be a ferroelectric capacitor used in a FRAM cell, and the capacitor dielectric may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As shown in FIG. 1A, in some implementations, the vertical transistors 126 are disposed vertically between the capacitors 128 and the bonding interface 106. That is, the vertical transistors 126 can be arranged closer to the peripheral circuits 112 of the first semiconductor structure 102 and the bonding interface 106 than the capacitors 128. Since the at least one bit line layer 123 and the capacitors 128 are coupled to opposite ends of the vertical transistors 126, the at least one bit line layer 123 (as part of the interconnect layer 122) are disposed vertically between the vertical transistors 126 and the bonding interface 106 As a result, the interconnect layer 122 including at least one bit line layer 123 can be arranged close to the bonding interface 106 to reduce the interconnect routing distance and complexity.

In some implementations, the second semiconductor structure 104 further includes a substrate 148 disposed above the DRAM cells 124. The substrate 148 can be part of a carrier wafer. It is understood that in some examples, the substrate 148 may not be included in the second semiconductor structure 104.

As shown in FIG. 1A, the second semiconductor structure 104 can further include a pad-out interconnect layer 150 above the substrate 148 and the DRAM cells 124. The pad-out interconnect layer 150 can include interconnects, e.g., contact pads 154, in one or more ILD layers. The pad-out interconnect layer 150 and the interconnect layer 122 can be formed on opposite sides of the DRAM cells 124. The capacitors 128 can be disposed vertically between the vertical transistors 126 and the pad-out interconnect layer 150. In some implementations, the interconnects in pad-out interconnect layer 150 can transfer electrical signals between the 3D semiconductor device 100 and outside circuits, e.g., for pad-out purposes.

In some implementations, the second semiconductor structure 104 further includes one or more contacts 152 extending through the substrate 148 and part of the pad-out interconnect layer 150 to couple the pad-out interconnect layer 150 to the DRAM cells 124 and the interconnect layer 122. As a result, the peripheral circuits 112 can be coupled to the DRAM cells 124 through the interconnect layers 116 and 122 as well as the bonding layers 120 and 118, and the peripheral circuits 112 and the DRAM cells 124 can be coupled to outside circuits through contacts 152 and pad-out interconnect layer 150. Contact pads 154 and contacts 152 can include conductive materials including, but not limited to, W, Co, Cu, Al, silicides, or any combination thereof. In one example, the contact pad 154 may include Al, and the contact 152 may include W. In some implementations, the contact 152 includes a via surrounded by a dielectric spacer (e.g., having silicon oxide) to electrically separate the via from substrate 148. Depending on the thickness of substrate 148, contact 152 can be an ILV having a depth in the submicron level (e.g., between 10 nm and 1 μm), or a TSV having a depth in the micron- or tens micron-level (e.g., between 1 μm and 100 μm).

Although not shown, it is understood that the pad-out of 3D memory devices is not limited to from the second semiconductor structure 104 having DRAM cells 124 as shown in FIG. 1A and may be from the first semiconductor structure 102 having peripheral circuit 112. Although not shown, it is also understood that the air gaps between word lines and/or between semiconductor bodies 130 may be partially or fully filled with dielectrics. Although not shown, it is further understood that more than one array of DRAM cells 124 may be stacked over one another to vertically scale up the number of DRAM cells 124.

In some implementations, instead of having the substrate 148 above the DRAM cells 124 as shown in FIG. 1A, the second semiconductor structure 104 includes a substrate disposed below the DRAM cells 124. The substrate can be part of a carrier wafer. The DRAM cells 124 can be formed in a front side of the substrate, and the at least one bit line layer 123 can be formed in a back side of the substrate. The at least one bit line layer 123 can be conductively coupled to the DRAM cells 124 (e.g., the terminals 158 of the vertical transistors 126) through the substrate.

FIG. 1C shows a side view of a cross-section of an example 3D semiconductor device 100c. The 3D semiconductor device 100c can be the 3D semiconductor device 100 of FIG. 1A-1B or a structure at an intermediate fabrication process of the 3D semiconductor device 100 of FIG. 1A.

As shown in FIG. 1C, the semiconductor device 100c can include memory cells 124 with a vertical transistor 126. The vertical transistor 126 of the memory cells 124 can include a semiconductor body 130 and a gate structure 136. The gate structures 136 of the vertical transistors 126 of two adjacent memory cells 124 extend long a vertical direction (e.g., the Z direction) in a first trench structure 132. In some implementations, the semiconductor body 130 of the vertical transistor 126 of the memory cell 124 can include a first terminal 156 and a second terminal 158 at opposite ends of the semiconductor body 130 along the Z direction. In some implementations, the semiconductor device 100c can include a diffusion region 168 that surrounds a first end 132-1 of the first trench structure 132. The first end 132-1 of the first trench structure 132 is closer to the second terminal 158 of the vertical transistor 126 of the memory cell 124 than the first terminal 156 of the vertical transistor 126 of the memory cell 124. In some implementations, the diffusion region 168 includes a first curved region 168a and a second curved region 168b. In some implementations, e.g., as illustrated in FIG. 1C, a length H1 of the first trench structure 132 surrounded by the first curved region 168a is greater than a second length H2 of the first trench structure surrounded by the second curved region 168b. In some implementations, the diffusion region 168 can be similar to, or same as the diffusion region 166 of the semiconductor device 100 of the FIG. 1A. In some implementations, the first terminal 156 can be a source structure and the second terminal 158 can be a drain structure. In some implementations, the first terminal 156 is coupled to a capacitor 170. In some implementations, the capacitor 170 is similar to, or same as the capacitor 128 of the semiconductor device 100 of FIG. 1A. In some implementations, the second terminal 158 of the memory cells 124 form a single second terminal 158. The second terminal 158 is connected to the corresponding at least one bit line layer 123 through an ohmic contact.

As shown in FIG. 1C, in some implementations, the first trench structure 132 can include a first isolation structure 133 in at least a portion of the first trench structure 132 from a second end 132-2 of the first trench structure 132, the second end 132-2 of the first trench structure 132 being closer to the first terminal 156 than the second terminal 158 along the Z direction. The gate structures 136 are surrounded by the first isolation structure 133 along the X direction. In some implementations, the first trench structure 132 can include a first isolation space 135 defined by a remaining portion of the first trench structure 132 from a first end 132-1 of the first trench structure 132 along the Z direction. The first isolation space 135 extends into a portion of the first isolation structure 133 along the Z direction. In some implementations, the first isolation space 135 is in contact the with gate structures 136. In some implementations, a length of the first trench structure 132 along the Z direction is in a range from about 255 nm to about 275 nm. In some implementations, a length of the gate structure 136 along the Z direction is in a range from about 80 nm to about 90 nm.

Each vertical transistor 126 of the memory cell 124 can include a second trench structure 164. The second trench structure 164 is between two adjacent vertical transistors 126 of the memory cells 124. In some implementations, the first terminal 156 of the vertical transistor 126 and the second terminal 158 of the vertical transistor 126 are at the opposite ends of the semiconductor body 130 of the memory cell 124 along the Z direction, and the second trench structure 164 is between two adjacent first trench structures 132 along the X direction. In some implementations, the second trench structure 164 can include a second isolation structure 160 in at least a portion of the second trench structure 164 from a second end 164-2 of the second trench structure 164. The second end 164-2 of the second trench structure 164 is closer to the first terminal 156 of the vertical transistor 126 of the memory cell 124 than the second terminal 158 of the vertical transistor 126 of the memory cell 124 along the Z direction. In some implementations, the second trench structure 164 can include a second isolation space 165 defined by a remaining portion of the second trench structure 164 from the first end 164-1 of the second trench structure 164 along the Z direction. The second isolation space 165 extends into a portion of the second isolation structure 160 along the Z direction.

FIG. 1D illustrate an example semiconductor device 100d along cut line AA′ of FIG. 1A. The 3D semiconductor device 100d can be the 3D semiconductor device 100 of FIG. 1A-1B or a structure at an intermediate fabrication process of the 3D semiconductor device 100 of FIG. 1A.

As shown in FIG. 1D, the semiconductor device 100d the semiconductor device 100c can include memory cells 124 with a vertical transistor 126. The vertical transistor 126 of the memory cells 124 can include a semiconductor body 130 and a gate structure 136 in a first trench structure 132. Each first trench structure 132 can include a first isolation structure 133 surrounding the gate structure 136. The first isolation structure 133 is between the semiconductor body 130 and the gate structure 136 along a horizontal direction (e.g., the X direction). In some implementations, each vertical transistor 126 of the memory cell 124 can include a second trench structure 164. The second trench structure 164 is between two adjacent vertical transistors 126 of the memory cells 124. In some implementations, the second trench structure 164 is between two adjacent first trench structures 132 along the X direction. In some implementations, the second trench structure 164 can include a second isolation structure 160 in contact with the semiconductor body 130 along the X direction. In some implementations, the second trench structure 164 can include a second isolation space 165 connected to the isolation structure 160 along the X direction. Each memory cells 124 are separated by the second trench structure 164 along the X direction and an oxide spacer 174 along a vertical direction (e.g., the Y direction) perpendicular to the X direction. As shown in FIG. 1D the gate structure 136 of each vertical transistor 126 of each memory 124 is a part of word line 174. The word line 174 extends through the oxide spacer 174 along the Y direction.

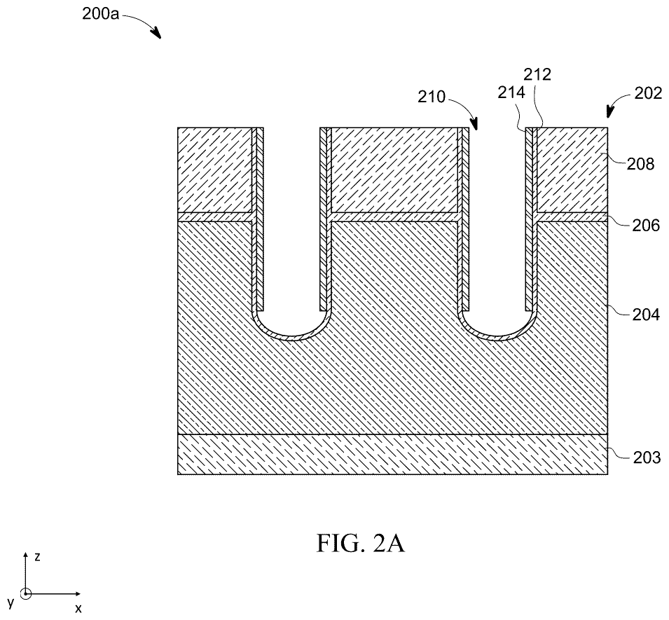

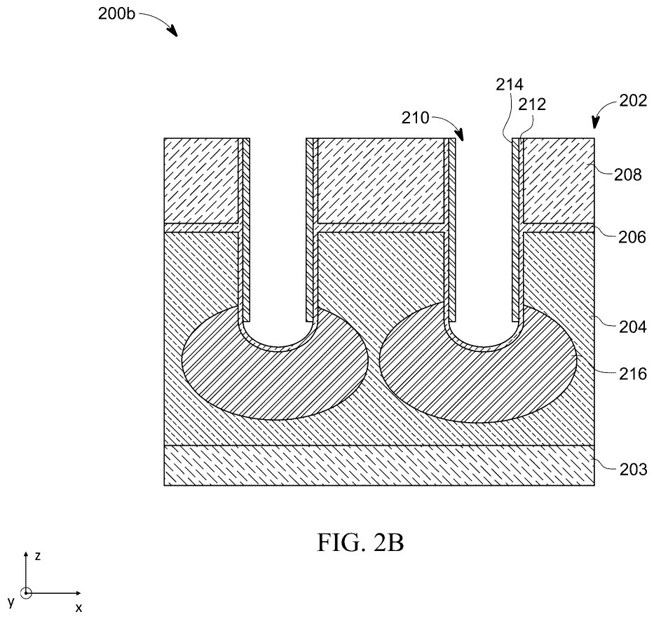

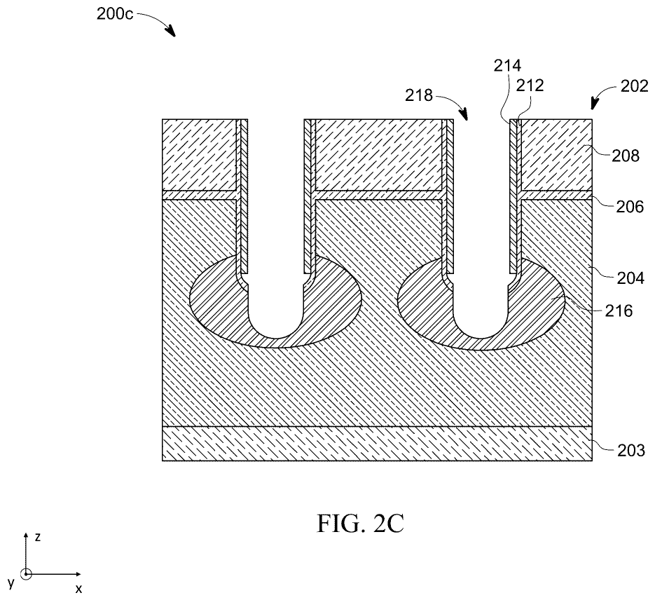

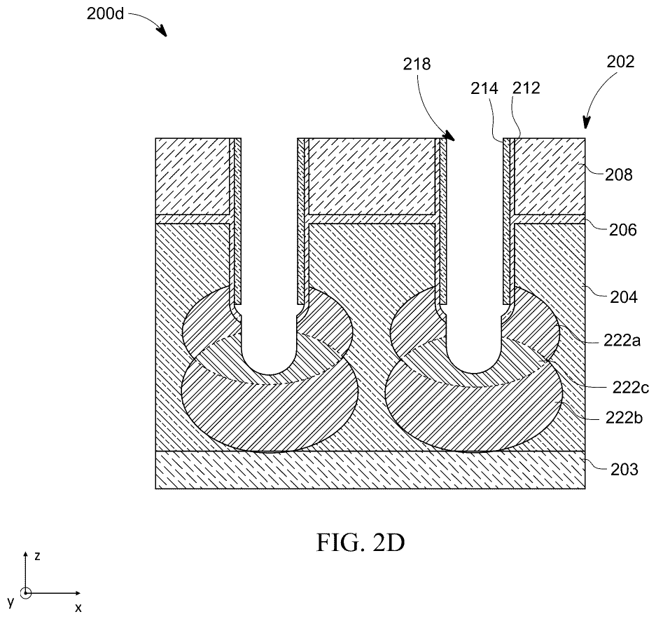

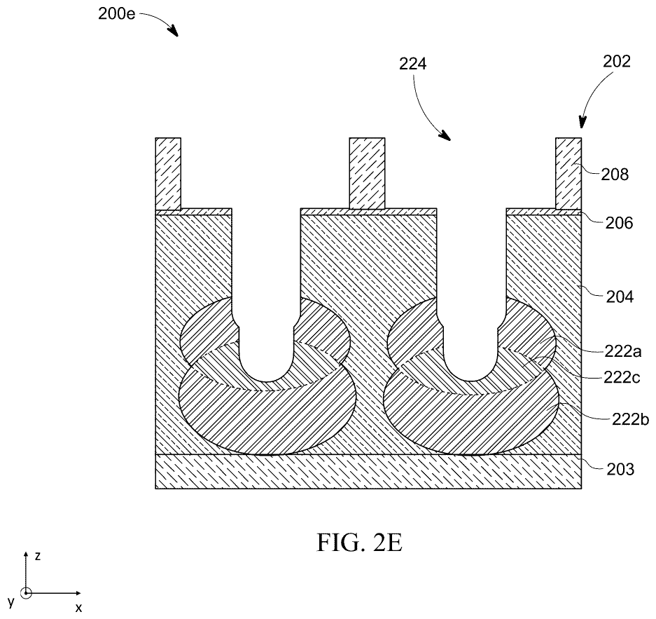

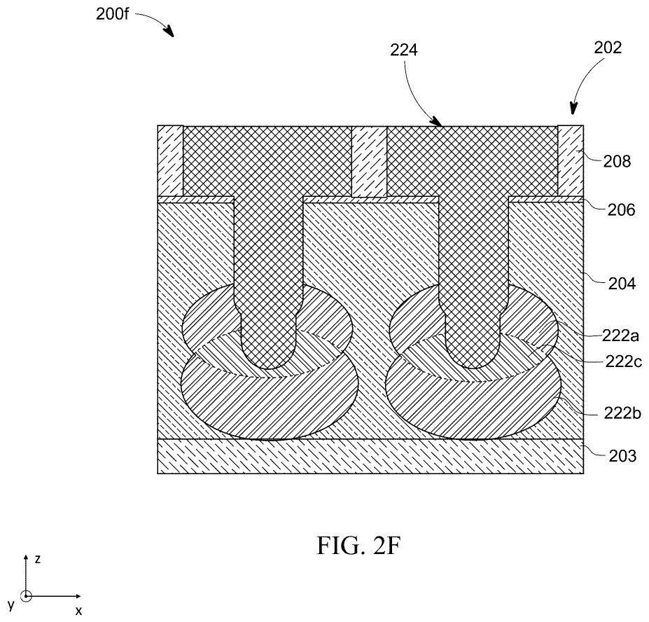

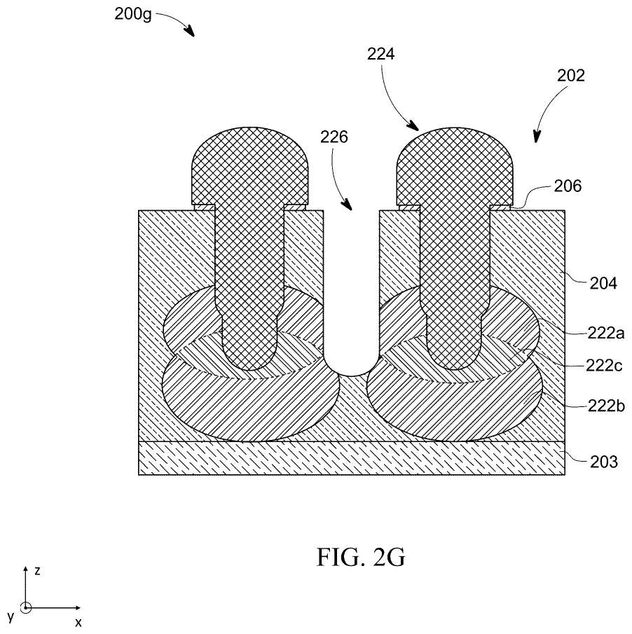

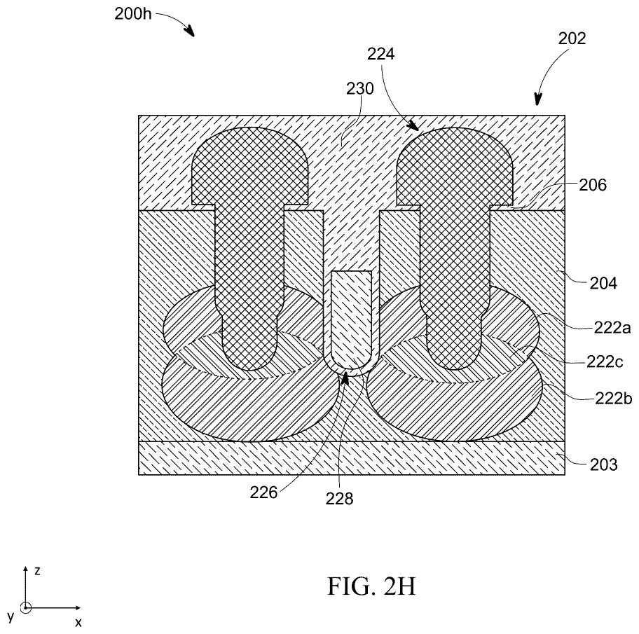

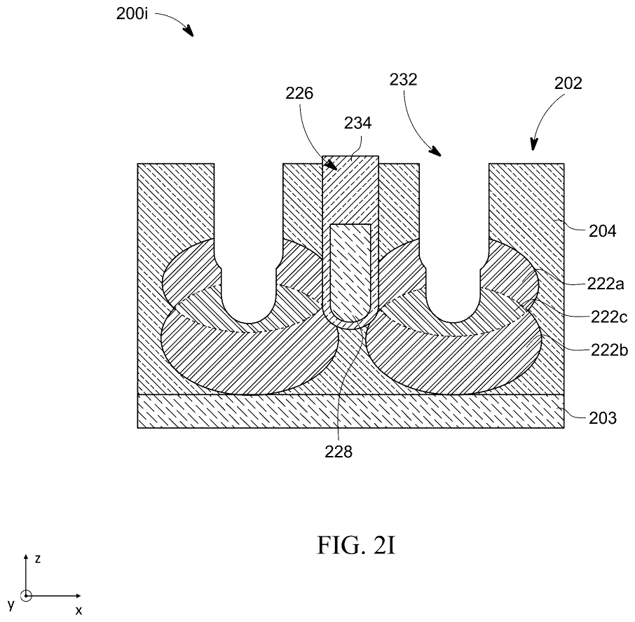

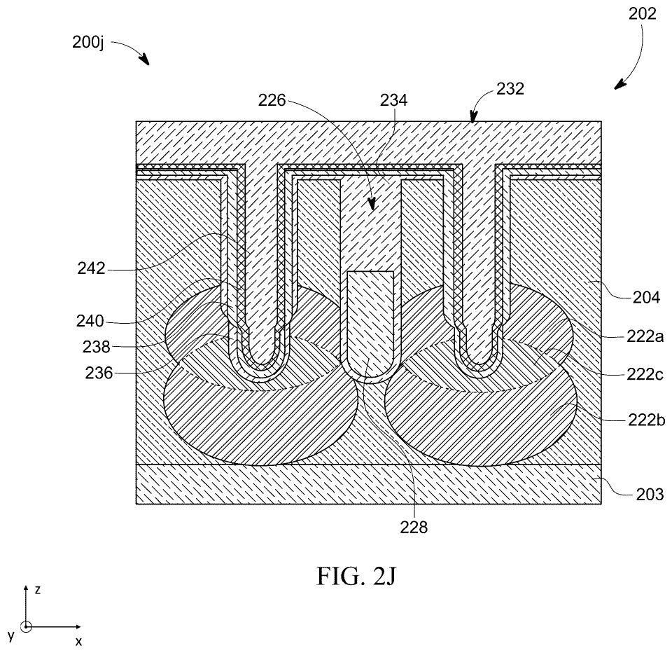

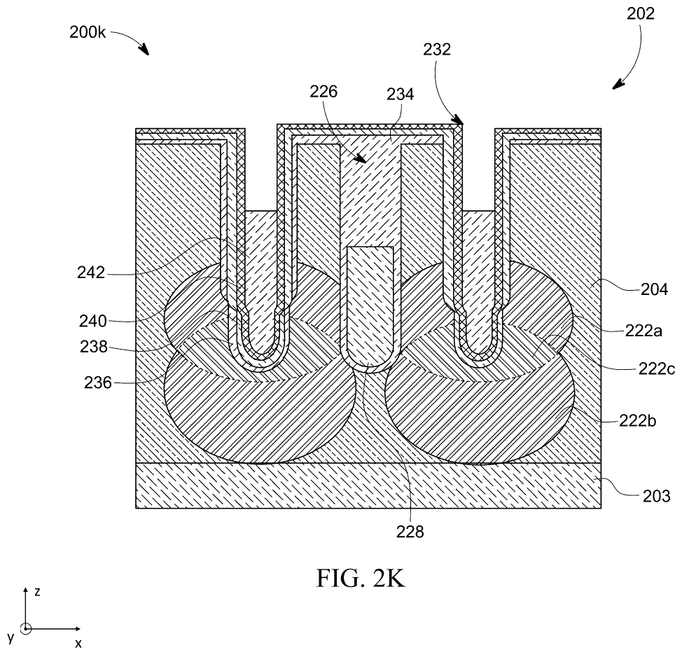

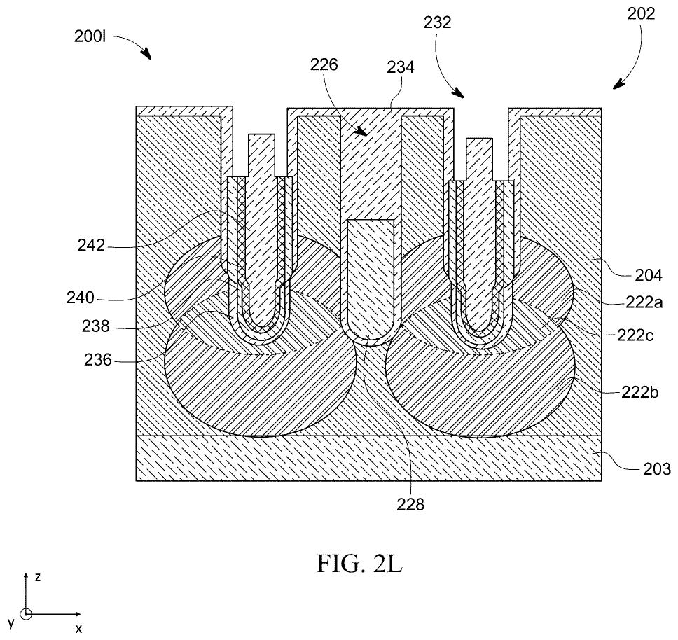

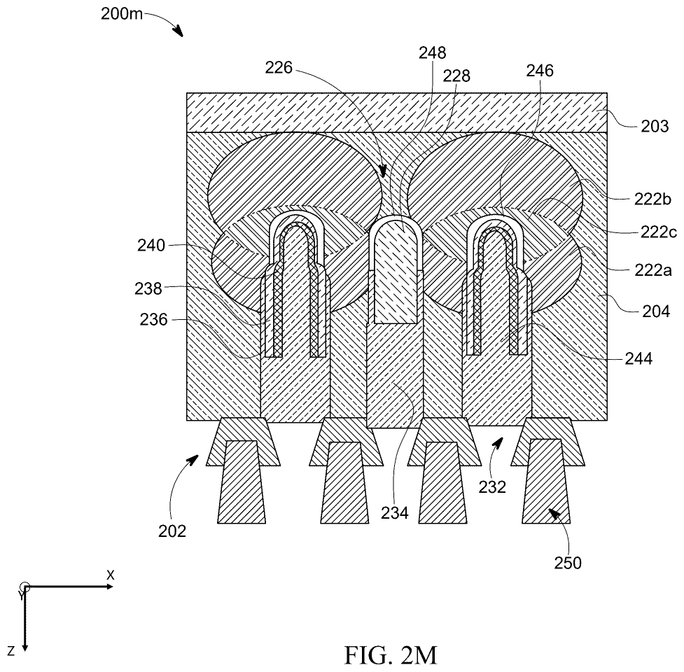

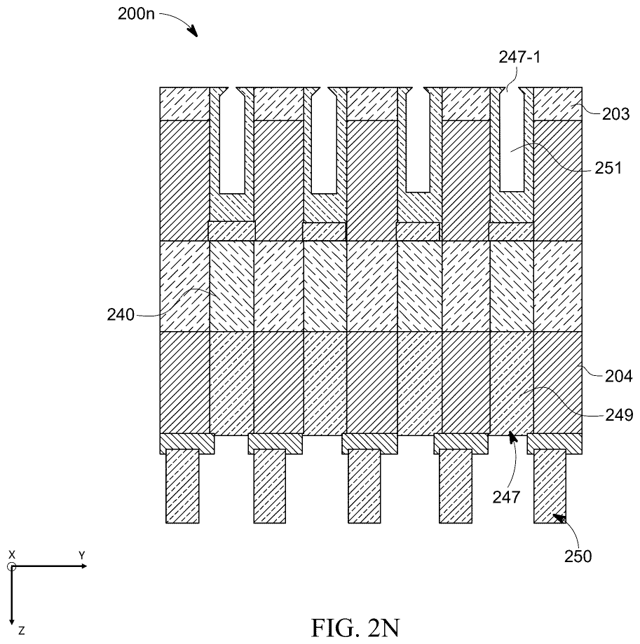

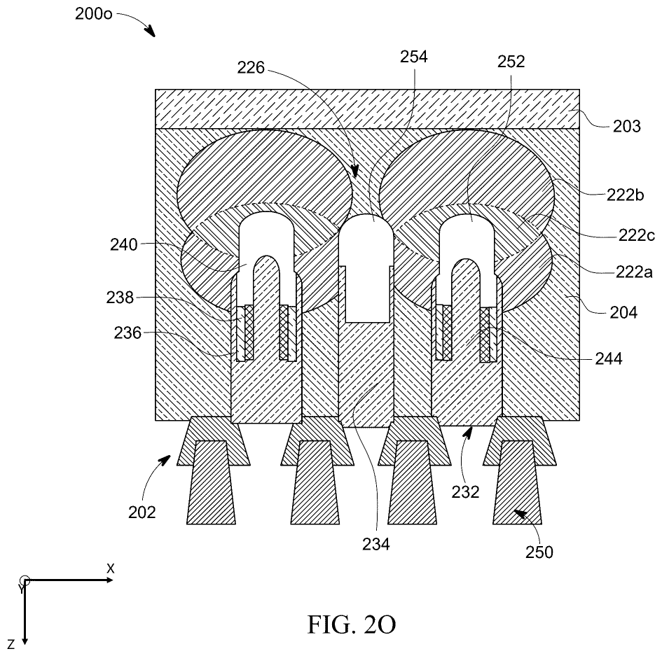

FIG. 2A-2O illustrate an example process of fabricating a semiconductor device, such as the semiconductor device 100 as illustrated in FIG. 1A. FIG. 2A-2O show cross sectional views of example semiconductor structures at various stages of the fabrication process.

As shown in FIG. 2A, a semiconductor structure 200a is formed. The semiconductor structure 200a can include a stack 202 of semiconductor substrate 204, an isolating layer 206 and a first dielectric layer 208 stacked on top of the at least one bit line layer 203 along a vertical direction (e.g., the Z direction). The at least one bit line layer 203 and the isolating layer 206 are connected to opposite sides of the semiconductor substrate 204 along the Z direction. The semiconductor structure 200a can include one or more first trenches 210, which is formed by etching one or more portions of the stack 202 along the Z direction. The one or more first trenches 210 can include a second dielectric layer 212, which can be formed by coating a first dielectric material on an inner wall of the one or more first trenches 210. The one or more first trenches 210 can also include a third dielectric layer 214, which can be formed by depositing a second dielectric material on the second dielectric layer 212 and etching a bottom portion of the second dielectric layer along the Z direction. In some implementations, the first dielectric material (e.g., SiO2) of the second dielectric layer 212 is different from the second dielectric material (e.g., AlO) of the third dielectric layer 214. In some implementations, the first dielectric material of the second dielectric layer 212 can be similar to, or same as a dielectric material of the isolating layer 206.

FIG. 2B illustrates a semiconductor structure 200b, which can be formed by implanting a dopant at an end of the one or more first trenches 210 with a first concentration profile of the dopant to form first diffusion regions 216.

FIG. 2C illustrates a semiconductor structure 200c, which can be formed by deepening the one or more first trenches 210 along the Z direction into the first diffusion regions 216 in the semiconductor substrate 204 to from one or more second trenches 218.

FIG. 2D illustrates a semiconductor structure 200d, which can be formed by implanting the dopant at an end of the one or more second trenches 218 with a second concentration profile of the dopant to form second diffusion regions. In some implementations, the first diffusion region 216 and the second diffusion region overlap to form overlap regions. In some implementations, first diffusion portion 222a is defined by the first diffusion region 216 without the overlap region, second diffusion portion 222b is defined by the second diffusion region without the overlap region, and middle diffusion portion 222c is the overlap region between the first diffusion region 216 and the second diffusion region.

FIG. 2E illustrates a semiconductor structure 200e, which can be formed by removing a portion of the first dielectric layer 208, the second dielectric layer 212 and the third dielectric layer 214 to form one or more third trenches 224.

FIG. 2F illustrates a semiconductor structure 200f, which can be formed by filling a conductive material in to the one or more third trenches 224.

FIG. 2G illustrates a semiconductor structure 200g, which can be formed by removing a portion of the isolating layer 206 and a remaining portion of the first dielectric layer 208. The semiconductor structure 200g can also include one or more fourth trenches 226, which is formed by etching one or more portions of the stack 202 along the Z direction. The one or more fourth trenches 226 is spaced from the one or more third trenches 224 along a horizontal direction (e.g., the X direction) perpendicular to the Z direction. In some implementations, the fourth trench 226 is between two adjacent third trenches 224.

FIG. 2H illustrates a semiconductor structure 200h, which can be formed by depositing a sacrificial material (e.g., TiN) in the one or more fourth trenches 226 to form sacrificial structures 228. A dielectric material (e.g., SiO2) can be deposited in the one or more fourth trenches 226 and on a first side of the semiconductor structure 200h to form a dielectric structure 230. The sacrificial structures 280 can be surrounded by the dielectric material. The first side of the semiconductor structure 200h is closer to the first diffusion portion 222a than the at least one bit line layer 203 along the Z direction. The dielectric structure 230 is connected to the isolating layer 206 along the X direction. In some implementations, the dielectric material of the isolating layer 206 can be similar to, or same as the dielectric material of the dielectric structure 230.

FIG. 2I illustrates a semiconductor structure 200i, which can be formed by performing a planarization process, such as chemical mechanical polishing (CMP), to remove the excess dielectric material in the dielectric structure 230 and the excess conductive material in the one or more third trenches 224 on the first side of the semiconductor structure 200h. A remaining portion of the conductive material in the one or more third trenches is also removed through a wet etching process from form one or more fifth trenches 232. First isolation structures 234 are defined by a remaining portion of the dielectric structure 230 in the one or more fourth trenches 226.

FIG. 2J illustrates a semiconductor structure 200j, which can be formed by depositing a first isolation material (e.g., SiO2), a second isolation material (e.g., TiN), and a conductive material (e.g., W) in the one or more fifth trenches 232 and on a first side of the semiconductor structure 200i to form a first isolation layer 236, a second isolation layer 238, and a conductive layer 240. The first side of the semiconductor structure 200i is closer to the first diffusion portion 222a than the at least one bit line layer 203 along the Z direction. The semiconductor structure 200j can also include an isolation stack 242, which can be formed by filling a remaining portion of the one or more fifth trenches 232 with a dielectric material (e.g., SiO2). In some implantations, the dielectric material of the isolation stack 242 can be similar to, or same as the first isolation material of the first isolation layer 236.

FIG. 2K illustrates a semiconductor structure 200k, which can be formed by performing a planarization process to remove the excess dielectric materials of the isolation stack 242 on a first side of the semiconductor structure 200j. The first side of the semiconductor structure 200j is closer to the first diffusion portion 222a than the at least one bit line layer 203 along the Z direction. A portion of the isolation stack 242 in the one or more fifth trenches 232 is also removed through a wet etching process.

FIG. 2L illustrates a semiconductor structure 200l, which can be formed by removing a portion of the second isolation layer 238 and the conductive layer 240 on a first side of the semiconductor structure 200k. The first side of the semiconductor structure 200k is closer to the first diffusion portion 222a than the at least one bit line layer 203 along the Z direction. A portion of the second isolation layer 238 and the conductive layer 240 in the one or more fifth trenches 232 is also removed from the first side of the semiconductor structure 200k through an etching process.

FIG. 2M illustrates a semiconductor structure 200m, which can be formed by filling a remaining portion of the one or more fifth trenches 232 with the first isolation material connected to the isolation stack 242 to form one or more second isolation structures 244. The semiconductor structure 200m can include first recess regions 246 which can be formed by etching a portion of the first isolation layer 236 of the one or more fifth trenches 232 from a second side of the semiconductor structure 200m. The second side of the semiconductor structure 200m is closer to the at least one bit line layer 203 than the first diffusion portion 222a along the Z direction. The semiconductor structure 200m can include second recess regions 248 which can be formed by etching a portion of the first isolation structures 234 of the one or more fourth trenches 226 from the second side of the semiconductor structure 200m. In some implementations, capacitors 250 is formed on a first side of the semiconductor structure 200m. The capacitors 250 is connected to the semiconductor substrate 204 along the Z direction. The first side of the semiconductor structure 200m is closer to the first diffusion portion 222a than the at least one bit line layer 203 along the Z direction.

FIG. 2N illustrates a side view of the semiconductor structure 200m, which can be formed by etching through the semiconductor substrate 204 and the at least one bit line layer 203 to one or more sixth trenches 247. The one or more sixth trenches separated the at least one bit line layer 203 into multiple segments. In some implementations, the one or more sixth trenches 247 can include one or more third isolation structures 249, which are formed by deposition a dielectric material (e.g., SiO2) in the one or more sixth trenches 247. Each six trench 247 is between two adjacent capacitors 250 of the semiconductor structure 200m. In some implementations, each sixth trench 247 can include a recess space 251, which is formed by etching a portion of the third isolation structure 249 from an end 247-1 of the sixth trench 247. The end 247-1 of the sixth trench 247 is closer to the at least one bit line layer 203 than the semiconductor substrate 204. The recess regions 246 and 248 of the semiconductor structure 200m of FIG. 2M are formed by filling an etching solution into the recess space 251 to etch a portion of the first isolation layer 236 and a portion of the first isolation structure 234 from the end 247-1 of the sixth trench 247.

FIG. 2O illustrates a semiconductor structure 200o. The semiconductor structure 200o includes first isolation spaces 252, and second isolation spaces 254. The first isolation spaces 252 are formed by etching a portion of the second isolation layer 238 and the conductive layer 240 in the one or more fifth trenches 232 from the second side of the semiconductor structure 200m through the first recess regions 246 and the recess space 251. The second isolation spaces 254 are formed by etching the sacrificial structure 228 in the one or more fourth trenches 226 from the second side of the semiconductor structure 200m through the second recess regions 248 and recess space 251.

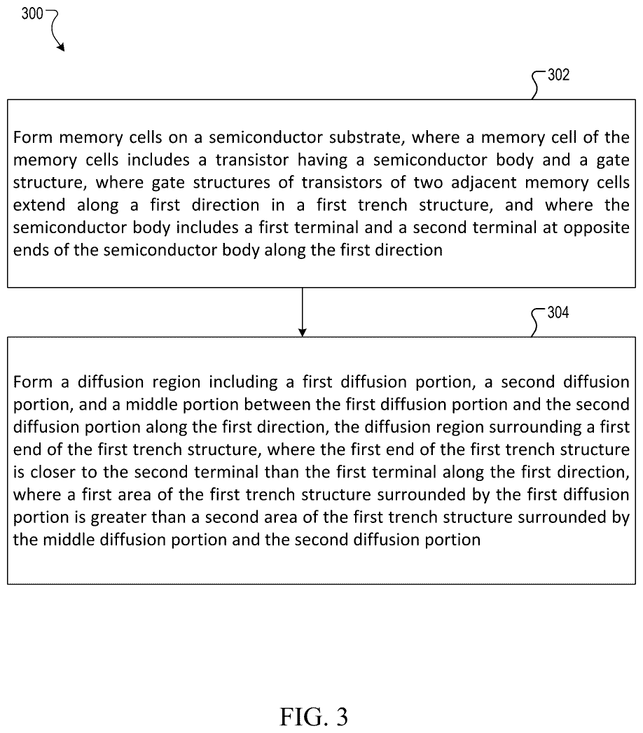

FIG. 3 illustrates a flow chart of an example process 300. The process 300 can be performed to form a semiconductor device (e.g., the semiconductor device 100 illustrated by FIG. 1A or the semiconductor device 100c illustrated by FIG. 1C). The process 300 can be described in view of FIG. 2A-2O. The process 300 can include one or more steps of the fabrication process of forming the semiconductor structures in FIG. 2A-2O. It is understood that the operations shown in process 300 are not exhaustive and that other operations can be performed as well before, after, or between any of the illustrated operations. Further, some of the operations may be performed simultaneously, or in a different order than shown in FIG. 3.

At operation 302, a semiconductor structure is formed. The semiconductor structure includes memory cells (e.g., the memory cells 124 in FIG. 1A) in a semiconductor substrate (e.g., the semiconductor substrate 204 in FIG. 2A), where a memory cell of the memory cells includes a transistor (e.g., the vertical transistor 126 in FIG. 1A) having a semiconductor body (e.g., the semiconductor body 130 in FIG. 1A) and a gate structure (e.g., the gate structure 136 in FIG. 1A), where gate structures of transistors of two adjacent memory cells extend along a first direction (e.g., the Z direction) in a first trench structure (e.g., the fifth trench 232 of FIG. 2O), and where the semiconductor body includes a first terminal (e.g., the first terminal 156 in FIG. 1A) and a second terminal (e.g., the second terminal 158 in FIG. 1A) at opposite ends of the semiconductor body along the first direction.

At operation 304, a diffusion region (e.g., the diffusion region 166 in FIG. 1A) including a first diffusion portion (e.g., the first diffusion portion 222a in FIG. 2D), a second diffusion portion (e.g., the second diffusion portion 222b in FIG. 2D), and a middle portion (e.g., the middle diffusion portion 222c in FIG. 2D) between the first diffusion portion and the second diffusion portion along the first direction is formed. The diffusion region surrounding a first end (e.g., the first end 132-1 in FIG. 1A) of the first trench structure, where the first end of the first trench structure is closer to the second terminal than the first terminal along the first direction, where a first area (e.g., the first area 163a of FIG. 1A) of the first trench structure surrounded by the first diffusion portion is greater than a second area (e.g., the second area 163b of FIG. 1A) of the first trench structure surrounded by the middle diffusion portion and the second diffusion portion.

In some implementations, the process 300 further including forming the first trench structure, where forming the first trench structure includes etching a portion of the semiconductor substrate along the first direction to form a first trench (e.g., the one or more first trenches 210 in FIG. 2A), where forming the diffusion region includes: implanting a dopant at an end of the first trench with a first concentration profile of the dopant to form a first diffusion region (e.g., the first diffusion region 216 in FIG. 2B); deepening the first trench by etching the first diffusion region from the end of the first trench along the first direction into the first diffusion region in the semiconductor substrate to form a second trench (e.g., the one or more second trenches 218 in FIG. 2C); and implanting the dopant at a first end (e.g., the first end 132-1 in FIG. 1A) of the second trench with a second concentration profile of the dopant to form a second diffusion region, where an overlap region of the first diffusion region and the second diffusion region forms the middle diffusion portion, and the first diffusion portion is defined by the first diffusion region without the overlap region, and the second diffusion portion is defined by the second diffusion region without the overlap region, and where the first diffusion portion has a first curved boundary (e.g., the first curved boundary 167a of FIG. 1A), and the second diffusion portion has a second curved boundary (e.g., the second curved boundary 167b of FIG. 1A), and where the first curved boundary and the second curved boundary are in contact at ends of the middle portion.

In some implementations, the middle portion has a third concentration profile of the dopant, and the third concentration profile is based on the first concentration profile and the second concentration profile, and where a concentration of the diffusion region has at least three peaks along the first direction, where a first peak is located in the first diffusion portion, a second peak is located in the middle portion, and a third peak is located in the second diffusion portion.

In some implementations, forming the first trench structure further includes depositing one or more filling layers in the second trench, where the one or more filling layers include an isolation layer (e.g., the first isolation layer 236 in FIG. 2J), an adhesive layer (e.g., the second isolation layer 238 in FIG. 2J), and a conductive layer (e.g., the conductive layer 240 in FIG. 2J); filling a remaining portion of the second trench with an isolation material to form an isolation stack (e.g., the isolation stack 242 in FIG. 2J); removing a portion of the adhesive layer and the conductive layer from a second end of the second trench to form a space; and filling the space with the isolating material connected to the isolation layer and the isolation stack to form an isolation structure (e.g., the second isolation structure 244 in FIG. 2M).

In some implementations, forming the first trench structure further includes forming an isolation space (e.g., the first isolation space 252 in FIG. 2O), where forming the isolation space includes etching a portion of the isolation layer in the second trench from the first end of the second trench; and etching a portion of the adhesive layer and the conductive layer from the first end of the second trench to form the isolation space, where gate structures of transistors of two adjacent memory cells include remaining portions of the adhesive layer and the conductive layer.

In some implementations, the process 300 further includes forming at least one bit line layer (e.g., the at least one bit line layer 203 in FIG. 2A) stacked with the memory cells along the first direction, where the at least one bit line layer is coupled to the second terminal of the two adjacent memory cells through an ohmic contact.

In some implementations, the process 300 further includes forming a second trench structure (e.g., the one or more fourth trench 226 in FIG. 2O) extending along the first direction and between two adjacent first trench structures along a second direction perpendicular (e.g., the X direction) to the first direction, where two adjacent diffusion regions associated with the two adjacent first trench structures are spaced from the second trench structure.

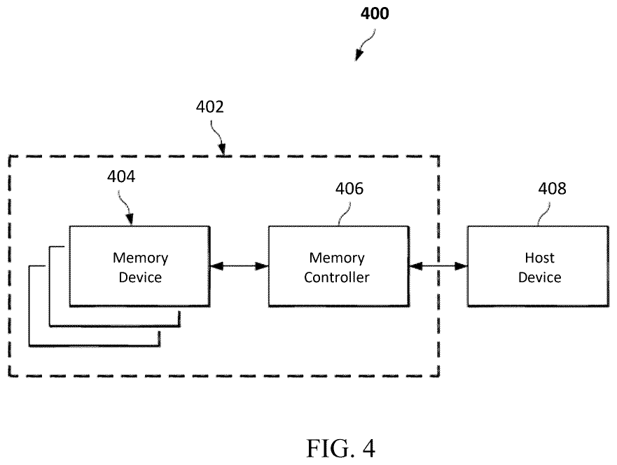

FIG. 4 illustrates a block diagram of a system 400 having one or more semiconductor devices (e.g., memory devices), according to one or more implementations of the present disclosure. The system 400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 4, the system 400 can include a host device 408 and a memory system 402 having one or more 3D memory devices 404 and a memory controller 406. Host device 408 can include a processor of an electronic device, such as a central processing unit (CPU), or a system-on-chip (SoC), such as an application processor (AP). Host device 408 can be configured to send or receive data to or from the one or more 3D memory devices 404.

A 3D memory device 404 can be any 3D memory device disclosed herein, such as a 3D memory device depicted in FIGS. 1A-1C, 2A-2O, or 3. In some implementations, a 3D memory device 404 includes a DRAM memory. Memory controller 406 (a.k.a., a controller circuit) is coupled to 3D memory device 404 and host device 408. Consistent with implementations of the present disclosure, 3D memory device 404 can include a plurality of conductive interconnections through a cover layer that ar1e in contact with conductive pads in a conductive pad layer, and memory controller 406 can be coupled to 3D memory device 404 through at least one of the plurality of conductive interconnections. Memory controller 406 is configured to control 3D memory device 404. For example, memory controller 406 may be configured to operate a plurality of channel structures via word lines. Memory controller 406 can manage data stored in 3D memory device 404 and communicate with host device 408.

In some implementations, memory controller 406 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 406 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 406 can be configured to control operations of 3D memory device 404, such as read, erase, and program (or write) operations. Memory controller 406 can also be configured to manage various functions with respect to the data stored or to be stored in 3D memory device 404 including, but not limited to bad-block management, garbage collection, logical-to-physical address conversion, wear leveling, etc. In some implementations, memory controller 406 is further configured to process error correction codes (ECCs) with respect to the data read from or written to 3D memory device 404. Any other suitable functions may be performed by memory controller 406 as well, for example, formatting 3D memory device 404.

Memory controller 406 can communicate with an external device (e.g., host device 408) according to a particular communication protocol. For example, memory controller 406 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 406 and one or more 3D memory devices 404 can be integrated into various types of storage devices, for example, be included in the same package, such as a universal Flash storage (UFS) package or an eMMC package. That is, memory system 402 can be implemented and packaged into different types of end electronic products. In one example as shown in FIG. 4, memory controller 406 and a single 3D memory device 404 may be integrated into a memory card 402. Memory card 402 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
memory cells, wherein a memory cell of the memory cells comprises a transistor having a semiconductor body and a gate structure, wherein gate structures of transistors of two adjacent memory cells extend along a first direction in a first trench structure, and wherein the semiconductor body comprises a first terminal and a second terminal at opposite ends of the semiconductor body along the first direction; and
a diffusion region comprising a first diffusion portion, a second diffusion portion, and a middle portion between the first diffusion portion and the second diffusion portion along the first direction, the diffusion region surrounding a first end of the first trench structure, wherein the first end of the first trench structure is closer to the second terminal than the first terminal along the first direction,
wherein a first area of the first trench structure surrounded by the first diffusion portion is greater than a second area of the first trench structure surrounded by the middle diffusion portion and the second diffusion portion.

2. The semiconductor device of claim 1, wherein the first diffusion portion has a first curved boundary, and the second diffusion portion has a second curved boundary, and
wherein the first curved boundary and the second curved boundary are in contact at ends of the middle portion.

3. The semiconductor device of claim 2, wherein the first curved boundary is in contact with the first trench structure at a contact position, and
wherein, along the first direction, a first length between the contact position and the ends of the middle portion is greater than a second length between the ends of the middle portion and the first end of the first trench structure.

4. The semiconductor device of claim 1, wherein the first trench structure further comprises:
an isolation structure in at least a portion of the first trench structure from a second end of the first trench structure, the second end of the first trench structure being closer to the first terminal than the second terminal along the first direction, wherein the gate structures are surrounded by the isolation structure along the second direction; and
an isolation space defined by a remaining portion of the first trench structure from the first end of the first trench structure along the first direction, wherein the isolation space extends into a portion of the isolation structure along the first direction, and wherein the isolation space is in contact with the gate structures.

5. The semiconductor device of claim 4, wherein, along the first direction, a length of the first trench structure surrounded by the diffusion region is greater than a length from an end of the isolation structure to the first end of the first trench structure, the end of the isolation structure being closer to the second terminal than the first terminal along the first direction.

6. The semiconductor device of claim 5, wherein, along the first direction, a length from the end of the isolation structure to the first terminal is greater than a length from an edge of the first diffusion portion to the first terminal along the first direction.

7. The semiconductor device of claim 5, wherein, along the first direction, the end of the isolation structure is farther from the first terminal of the transistor than an end of the gate structure, the end of the gate structure being closer to the second terminal than the first terminal along the first direction.

8. The semiconductor device of claim 4, wherein, along the first direction, a length from the first end of the first trench structure to an edge of the second diffusion portion is in a range from 20 nm to 40 nm, the edge of the second diffusion portion being closer to the second terminal than the first terminal.

9. The semiconductor device of claim 1, further comprising at least one bit line layer stacked with the memory cells along the first direction, wherein the at least one bit line layer is coupled to the second terminal of the two adjacent memory cells through an ohmic contact.

10. The semiconductor device of claim 1, wherein the first diffusion portion has a first concentration profile of a dopant, and the second diffusion portion has a second concentration profile of the dopant, and
wherein the middle portion has a third concentration profile of the dopant, and the third concentration profile is based on the first concentration profile and the second concentration profile.

11. The semiconductor device of claim 10, wherein a concentration of the diffusion region has at least three peaks along the first direction, wherein a first peak is located in the first diffusion portion, a second peak is located in the middle portion, and a third peak is located in the second diffusion portion.

12. The semiconductor device of claim 1, further comprising a second trench structure extending along the first direction and between two adjacent first trench structures along a second direction perpendicular to the first direction,
wherein two adjacent diffusion regions associated with the two adjacent first trench structures are spaced from the second trench structure.

13. A method of forming a semiconductor device, the method comprising:
forming memory cells on a semiconductor substrate, wherein a memory cell of the memory cells comprises a transistor having a semiconductor body and a gate structure, wherein gate structures of transistors of two adjacent memory cells extend along a first direction in a first trench structure, and wherein the semiconductor body comprises a first terminal and a second terminal at opposite ends of the semiconductor body along the first direction; and
forming a diffusion region comprising a first diffusion portion, a second diffusion portion, and a middle portion between the first diffusion portion and the second diffusion portion along the first direction, the diffusion region surrounding a first end of the first trench structure, wherein the first end of the first trench structure is closer to the second terminal than the first terminal along the first direction,
wherein a first area of the first trench structure surrounded by the first diffusion portion is greater than a second area of the first trench structure surrounded by the middle diffusion portion and the second diffusion portion.

14. The method of claim 13, further comprising forming the first trench structure, wherein forming the first trench structure comprises: etching a portion of the semiconductor substrate along the first direction to form a first trench,
wherein forming the diffusion region comprises:
implanting a dopant at an end of the first trench with a first concentration profile of the dopant to form a first diffusion region;
deepening the first trench by etching the first diffusion region from the end of the first trench along the first direction into the first diffusion region in the semiconductor substrate to form a second trench; and
implanting the dopant at a first end of the second trench with a second concentration profile of the dopant to form a second diffusion region,
wherein an overlap region of the first diffusion region and the second diffusion region forms the middle diffusion portion, and the first diffusion portion is defined by the first diffusion region without the overlap region, and the second diffusion portion is defined by the second diffusion region without the overlap region, and
wherein the first diffusion portion has a first curved boundary, and the second diffusion portion has a second curved boundary, and wherein the first curved boundary and the second curved boundary are in contact at ends of the middle portion.

15. The method of claim 14, wherein the middle portion has a third concentration profile of the dopant, and the third concentration profile is based on the first concentration profile and the second concentration profile, and wherein a concentration of the diffusion region has at least three peaks along the first direction, wherein a first peak is located in the first diffusion portion, a second peak is located in the middle portion, and a third peak is located in the second diffusion portion.

16. The method of claim 14, wherein forming the first trench structure further comprises:
depositing one or more filling layers in the second trench, wherein the one or more filling layers comprise an isolation layer, an adhesive layer, and a conductive layer;
filling a remaining portion of the second trench with an isolation material to form an isolation stack;
removing a portion of the adhesive layer and the conductive layer from a second end of the second trench to form a space; and
filling the space with the isolating material connected to the isolation layer and the isolation stack to form an isolation structure.

17. The method of claim 16, wherein forming the first trench structure further comprises forming an isolation space, wherein forming the isolation space comprises:
etching a portion of the isolation layer in the second trench from the first end of the second trench; and
etching a portion of the adhesive layer and the conductive layer from the first end of the second trench to form the isolation space, wherein gate structures of transistors of two adjacent memory cells comprise remaining portions of the adhesive layer and the conductive layer.

18. The method of claim 13, further comprising:
forming at least one bit line layer stacked with the memory cells along the first direction, wherein the at least one bit line layer is coupled to the second terminal of the two adjacent memory cells through an ohmic contact.

19. The method of claim 13, further comprising:
forming a second trench structure extending along the first direction and between two adjacent first trench structures along a second direction perpendicular to the first direction,
wherein two adjacent diffusion regions associated with the two adjacent first trench structures are spaced from the second trench structure.

20. A semiconductor device, comprising:
memory cells, wherein a memory cell of the memory cells comprises a transistor having a semiconductor body and a gate structure, wherein gate structures of transistors of two adjacent memory cells extend along a first direction in a first trench structure, and wherein the semiconductor body comprises a first terminal and a second terminal at opposite ends of the semiconductor body along the first direction; and
a diffusion region that surrounds a first end of the first trench structure, wherein the first end of the first trench structure is closer to the second terminal than the first terminal along the first direction,
wherein the diffusion region comprises a first curved region and a second curved region, and wherein, along the first direction, a first length of the first trench structure surrounded by the first curved region is greater than a second length of the first trench structure surrounded by the second curved region.
